(19) United States
(12) Patent Application Publication
(10) Pub. No.: US 2019/0280184 A1
(43) Pub. Date: Sep. 12, 2019

(54) Piezoelectric Transmission and/or Reception Device, Vibration Sensor and Associated Method

(71) Applicant: VEGA GRIESHABER KG, Wolfach (DE)

(72) Inventors: Volker Allgaier, Haslach i.K. (DE); Dominik Fehrenbach, Haslach (DE); Holger Gruhler, Tunningen (DE)

(21) Appl. No.: 16/345,504

(22) PCT Filed: Nov. 18, 2016
(86) PCT No.: PCT/EP2016/078172

§ 371 Date: Apr. 26, 2019

(51) Int. Cl. H01L 41/08; H01L 41/083; H01L 41/047; H01L 41/273; B06B 1/06; G01H 11/08

(52) U.S. Cl. CPC H01L 41/0825; H01L 41/0835; G01H 11/08; H01L 41/273; B06B 1/0666; H01L 41/0471

(57) ABSTRACT

Disclosed is a piezoelectric transmission and/or reception device consisting of at least one piezo element, at least two electrodes for making contact with the piezo elements and at least two insulating elements for providing top and bottom insulation, wherein at least the piezo element and the electrodes are sintered so as to form a single block.

### CROSS REFERENCE TO RELATED APPLICATIONS

This patent application claims priority to International Patent Application PCT/EP2016/078172, filed on Nov. 18, 2016.

### STATEMENT REGARDING FEDERALLY SPONSORED RESEARCH OR DEVELOPMENT

No federal government funds were used in researching or developing this invention.

### NAMES OF PARTIES TO A JOINT RESEARCH AGREEMENT

Not applicable.

### SEQUENCE LISTING INCLUDED AND INCORPORATED BY REFERENCE HEREIN

Not applicable.

### BACKGROUND

### Field of the Invention

The present invention relates to a piezoelectric transmission and/or reception device, vibration sensor comprising a piezoelectric transmission and/or reception device of said type, and method for manufacturing a piezoelectric transmission and/or reception device.

### Background of the Invention

The present invention relates to a piezoelectric transmission and/or reception device, a vibration sensor comprising such a piezoelectric transmission and/or reception device and a method for manufacturing such a piezoelectric transmission and/or reception device, each according to the following disclosure.

Piezoelectric transmission and/or reception devices, vibration sensors equipped with such transmission and/or reception devices, as well as methods for the production of piezoelectric transmission and/or reception devices are known from prior art, with the piezoelectric transmission and/or reception devices comprising at least one piezo-element, at least two electrodes for contacting the piezo-element, as well as at least two isolation elements for isolating towards the top and the bottom, with the individual elements to form piezoelectric transmission and/or reception devices being stacked loosely on top of each other. In order to ensure the correct alignment of the individual components they are either embodied in an annular fashion or arranged on a centrally arranged bolt, or the disk-shaped components are aligned in reference to each other in a sheath embodied as a housing.

The above-described piezoelectric transmission and/or reception devices may be used for example in vibration sensors, which are frequently used in fill level measuring technology as limit sensors, as transmission and/or reception devices. Frequently such piezoelectric transmission and/or reception devices are also called drives.

An electromechanical drive in a laminar design is known from WO 01/84642 A1, in which individual components, which are metal-coated at their mutually facing surfaces, are connected by way of diffusion welding. In order to allow connecting individual components to join with each other by way of diffusion welding, the surfaces abutting each other must show very high surface quality and the arrangement must be heated up to slightly below the solidus line of the material used for diffusion welding, so that then a solid connection of the individual components can form.

In the method using the technology of prior art, it is considered disadvantageous that the components provided for the diffusion welding must show a very high surface quality and a very high temperature must be given for the diffusion welding. In particular, in the piezoelectric transmission and/or reception devices underlying the present invention, this method can be used with difficulty only, since the piezo-elements lose their piezoelectric features when heated above their Curie-temperature, and thus become useless, or have to be newly polarized. Further, the components required for diffusion welding are expensive in their production and the manufacturing process is elaborate. This is caused by the expensive production of the necessary surface quality, as well as subsequent polarization of the piezo, which typically occurs at voltages from 500 to 1,000 V or more, and requires a protective atmosphere.

The objective of the present invention is to provide an improved piezoelectric transmission and/or reception device. In particular, considerably lower temperatures are sufficient for the production of it, so that it can be produced in a less costly and easier fashion. Further, the objective of the present invention is to provide a method for the production of such a piezoelectric transmission and/or reception device.

These objectives are attained in a piezoelectric transmission and/or reception device with the features and the method for producing a piezoelectric transmission and/or reception device with the features as described further herein. A vibration sensor with a piezoelectric transmission and/or reception device according to the invention is disclosed herein as well, along with advantageous additional embodiments.

### BRIEF SUMMARY OF THE INVENTION

In a preferred embodiment, a piezoelectric transmission and/or reception device (1) comprising
at least one piezo element (3),
at least two electrodes (5) for contacting the piezo elements (3), as well as
at least two isolation elements (7) for isolation at the top and the bottom,
   characterized in that at least the piezo element (3) and the electrodes (5) are sintered to form a mono-block.

In another preferred embodiment, the piezoelectric transmission and/or reception device (1) as described herein, characterized in that the mono-block comprises additionally the isolation elements (7).

In another preferred embodiment, the piezoelectric transmission and/or reception device (1) as described herein, characterized in that the piezoelectric transmission and/or reception device (1) comprises n-piezo elements (3) and n+1 electrodes (5), which are arranged in an alternating fashion and are sintered to form a mono-block.

In another preferred embodiment, the piezoelectric transmission and/or reception device (1) as described herein, characterized in that the piezoelectric transmission and/or reception device (1) comprises a transmission device (10) and a reception device (11), which respectively comprise n-piezo elements (3) and n+1 electrodes (5), which are arranged in an alternating fashion, with the transmission device (10) and the reception device (11) being electrically isolated from each other by the separating ceramic (13) and all components being sintered to form a mono-block.

In another preferred embodiment, the piezoelectric transmission and/or reception device (1) as described herein, characterized in that the mono-block comprises additionally a preferably metallic pressure part (15) for transmitting any oscillation generated.

In another preferred embodiment, the piezoelectric transmission and/or reception device (1) as described herein, characterized in that the piezo elements (3) and the electrodes (5) are embodied as annular disks.

In another preferred embodiment, the piezoelectric transmission and/or reception device (1) as described herein, characterized in that the piezo elements (3) and the electrodes (5) are embodied as annular disks.

In another preferred embodiment, the piezoelectric transmission and/or reception device (1) as described herein, characterized in that the piezo elements (3) show a thickness (d) of less than 1.0 mm, preferably less than 0.5 mm.

In another preferred embodiment, the piezoelectric transmission and/or reception device (1) as described herein, characterized in that the piezo elements (3) and/or the electrodes (5) and/or the isolation elements (7) and/or the separating ceramic (13) show an average surface roughness of more than 6.3, preferably more than 16.

In another preferred embodiment, the piezoelectric transmission and/or reception device (1) as described herein, characterized in that The mono-block is produced via a silver-sintering process.

In an alternate preferred embodiment, a vibration sensor (100) with a piezoelectric transmission and/or reception device (1) with a diaphragm (90) that can be made to vibrate, a clamping device (96) for clamping the piezoelectric transmission and/or reception device (1) towards the diaphragm (90) such that oscillations of the transmission and/or reception device (1) are transferred to the diaphragm (90) and the oscillations of the diaphragm (90) to the transmission and/or reception device (1), characterized in that the transmission and/or reception device (1) are embodied according to any of the previous claims.

In an alternate preferred embodiment, a method for the production of a piezoelectric transmission and/or reception device (1) with the following steps:
providing at least one piezo element (3), at least two electrodes (5) for contacting the piezo element (3), as well as at least two isolation elements (7) for isolation at the top and the bottom,
coating at least the piezo element (3) on its contacting sides as well as the electrodes (5) on their sides facing the piezo element (3) in the finished state of the arrangement with a sinter material on a silver base,
aligned arrangement of electrodes (5) and piezo element (3) in a stack,
sintering the stack for a predetermined sintering period (5) at a defined sinter temperature (T) to form a mono-block.

In another preferred embodiment, the method as described herein, characterized in that the coating process comprises the application of a sinter paste via template printing, a dispenser, or serigraphy, or the application of a sinter film.

In another preferred embodiment, the method as described herein, characterized in that the coating process comprises a drying step after the application.

In another preferred embodiment, the method as described herein, characterized in that a sintering material is used comprising silver particles with a size from 100 nm to 500 nm.

In another preferred embodiment, the method as described herein, characterized in that the sinter temperature (T) amounts to less than 300° C., preferably less than 280° C., further preferred ranges from 200° C. to 250° C.

In another preferred embodiment, the method as described herein, characterized in that the sintering process occurs at a pressure (p) of less than 20 MPa, preferably occurs at 5 MPa, further preferred at atmospheric pressure.

### BRIEF DESCRIPTION OF THE DRAWINGS

FIG. 1A is a line drawing evidencing a first exemplary embodiment of a piezoelectric transmission and/or reception device.

FIG. 1B is a line drawing evidencing an enlarged detail of FIG. 1a in an elevated illustration.

FIG. 2 is a line drawing evidencing a vibration sensor with the piezoelectric transmission and/or reception device of FIG. 1.

FIG. 3 is a line drawing evidencing a detail of a vibration sensor with a piezoelectric transmission and/or reception device according to a second exemplary embodiment.

FIG. 4 is a chart evidencing the sequence of a production method.

### DETAILED DESCRIPTION OF THE INVENTION

Piezoelectric transmission and/or reception devices, vibration sensors equipped with such transmission and/or reception devices, as well as methods for the production of piezoelectric transmission and/or reception devices are known from prior art, with the piezoelectric transmission and/or reception devices comprising at least one piezo-element, at least two electrodes for contacting the piezo-element, as well as at least two isolation elements for isolating towards the top and the bottom, with the individual elements to form piezoelectric transmission and/or reception devices being stacked loosely on top of each other. In order to ensure the correct alignment of the individual components they are either embodied in an annular fashion or arranged on a centrally arranged bolt, or the disk-shaped components are aligned in reference to each other in a sheath embodied as a housing.

The above-described piezoelectric transmission and/or reception devices may be used for example in vibration sensors, which are frequently used in fill level measuring technology as limit sensors, as transmission and/or reception devices. Frequently such piezoelectric transmission and/or reception devices are also called drives.

An electromechanical drive in a laminar design is known from WO 01/84642 A1, in which individual components, which are metal-coated at their mutually facing surfaces, are connected by way of diffusion welding. In order to allow connecting individual components to join with each other by way of diffusion welding, the surfaces abutting each other must show very high surface quality and the arrangement must be heated up to slightly below the solidus line of the material used for diffusion welding, so that then a solid connection of the individual components can form.

In the method using the technology of prior art, it is considered disadvantageous that the components provided for the diffusion welding must show a very high surface quality and a very high temperature must be given for the diffusion welding. In particular, in the piezoelectric transmission and/or reception devices underlying the present invention, this method can be used with difficulty only, since the piezo-elements lose their piezoelectric features when heated above their Curie-temperature, and thus become useless, or have to be newly polarized. Further, the components required for diffusion welding are expensive in their production and the manufacturing process is elaborate. This is caused by the expensive production of the necessary surface quality, as well as subsequent polarization of the piezo, which typically occurs at voltages from 500 to 1,000 V or more, and requires a protective atmosphere.

The objective of the present invention is to provide an improved piezoelectric transmission and/or reception device. In particular, considerably lower temperatures are sufficient for the production of it, so that it can be produced in a less costly and easier fashion. Further, the objective of the present invention is to provide a method for the production of such a piezoelectric transmission and/or reception device.

These objectives are attained in a piezoelectric transmission and/or reception device with the features of claim 1 as well as the method for producing a piezoelectric transmission and/or reception device with the features of claim 12. A vibration sensor with a piezoelectric transmission and/or reception device according to the invention is disclosed in claim 11.

Advantageous embodiments are disclosed in the dependent claims.

The piezoelectric transmission and/or reception device according to the invention comprises at least one piezo element, at least two electrodes for contacting the piezo element, as well as at least two isolation elements for the isolation towards the top and the bottom, with at least one piezo element and the electrodes being sintered to a mono-block. If applicable, it may be advantageous to electrically connect a piezoelectric transmission and/or reception device with the housing, in order to yield grounding.

Due to the fact that the piezo element and the electrodes are sintered to form a mono-block, they are connected to each other in a fixed manner such that their arrangement in reference to each other is set. It is therefore no longer necessary to provide additional devices or arrangements for centering piezo elements or electrodes in reference to each other. This is advantageous since, in addition to saving components here, an optimal alignment of piezo elements and electrodes in reference to each other is also ensured in this way, which simplifies the application of an optimal electric field at the piezo element, since a holohedral and completely overlapping alignment of electrodes and piezo element is ensured. The sintering process can be performed at low processing temperatures, so that the sintered component therefore shows low internal mechanic stress and thus also high quality and resistance.

For the sintering process preferably the sinter material, particularly sinter paste or sinter film on a silver base, is used with nano-scaled silver particles showing a size from 10 nm to 15 μm.

Another simplified arrangement can be achieved when the mono-block additionally comprises isolation elements. When the isolation elements arranged at the top and the bottom and provided with appropriate isolation are also sintered with the electrodes and at least one piezo element to form a mono-block, this way, a compact and uniformly handled arrangement is created.

In a first embodiment, the piezoelectric transmission and/or reception device comprises a number of n-piezo elements and n+1 electrodes, arranged alternating and sintered to form a mono-block.

In a second embodiment, the piezoelectric transmission and/or reception device comprises a transmission device and a reception device, which comprise respectively n-piezo elements and n+1 electrodes, arranged alternating, with the transmission device and the reception device being electrically isolated from each other by a separating ceramic and all components are sintered to form a mono-block.

In order to ensure optimal transmission of oscillations generated via the piezoelectric transmission and/or reception device upon other elements or oscillations of other elements upon the transmission and/or reception device, the mono-block may comprise additionally a pressure part, preferably made from a metallic or ceramic material. For this purpose, the pressure part can be embodied for example conically tapering starting with a diameter of the mono-block, such that a punctual or linear coupling or decoupling of oscillations is possible.

In order to allow using the here described piezoelectric transmission and/or reception device in already existing devices with a centrally arranged bolt, it may be advantageous for the piezo elements and the electrodes, and preferably the isolation elements and the pressure part, to be embodied in an annular fashion.

In order to yield higher forces of the piezoelectric transmission and/or reception devices, here a maximum surface of the piezo elements is required.

This can be achieved in a particularly easy fashion when the piezo elements and the electrodes are formed as circular disks.

Due to the fact that additional centering elements, such as a centrally arranged bolt and/or a sheath covering the components of the piezoelectric transmission and/or reception device can be waived, it is also possible to utilize the structural space available almost in its entirety in the radial direction so that a greater area is available to generate a piezoelectric effect and thus a stronger force can develop by the piezoelectric transmission and/or reception device.

In an advantageous embodiment, the piezo elements show a thickness of less than 0.1 mm, preferably less than 0.5 mm. Due to the fact that the piezo elements are sintered with the other components of the piezoelectric transmission and/or reception device to form a mono-block, it is possible to embody them with a reduced thickness since mechanic influences upon the piezo elements are here also avoided. In particular, the uneven surface characteristics of the piezo elements, the electrodes, or the ceramic elements used for isolation, are compensated by the sinter material used for the production here, so that additionally any mechanic influences upon the piezo elements are minimized. Due to the fact that that piezo elements can be embodied with a reduced thickness, with identical operating voltages of the piezoelectric transmission and/or reception device a higher electric field develops the piezo elements, allowing to utilize in the piezoelectric effect to a considerably better extent.

By the use of sinter material, particularly a sinter paste or sinter film when sintering the piezoelectric transmission and/or reception device, it is further possible to use piezo elements and/or the electrodes and/or the isolation elements and/or the separating ceramic with a greater average surface roughness of more than RZ (roughness grade number) 6.3, preferably more than RZ 16. This way it is possible to produce the piezo elements particularly at considerably reduced costs, so that the costs for the sintering process can be compensated entirely or at least partially.

The averaged surface roughness can particularly amount for the piezo elements to more than 6.3, for the isolation elements more than 4, and for the metallic parts more than 16.

Particularly low processing temperatures can be yielded for the production process of the mono-block when the mono-block is produced with a silver-sintering method. In such a silver-sintering method, preferably sinter paste or sinter film with nano-scaled silver is used, since they allow processing temperatures and pressures for the sintering method, which are considerably below the Curie-temperature of approx. 350° C. of the piezo elements used.

The piezoelectric transmission and/or reception device of the present invention can be used in a particularly beneficial fashion in a vibration sensor with a diaphragm set to oscillate, a tension device for stressing the piezoelectric transmission and/or reception device towards the diaphragm such that oscillations of the transmission and/or reception device are transferred to the diaphragm and oscillations of the diaphragm to the transmission and/or reception device.

The method according to the invention for the production of a piezoelectric transmission and/or reception device comprises the following steps:

providing at least one piezo element, at least two electrodes for contacting the piezo element, as well as at least two isolation elements for the isolation at the top and the bottom,

coating with a sinter material on a silver base at least the piezo element on its contacting sides as well as the electrodes on their side facing the piezo element in the finished state of the arrangement,

arranging electrodes and piezo elements in an aligned fashion in a stack,

sintering the stack for a predetermined sinter period at a defined sinter temperature to form a mono-block.

The method can be implemented in a particularly simple fashion when the coating process comprises the applying of the sinter material via template printing, a dispenser or serigraphy, or the application of a sinter film. The coating may further include a drying step after the application of the sinter material, particularly in the form of sinter paste, with this occurring in a drying kiln, for example.

Preferably a sinter material with silver particles showing a size from approx. 100 nm to approx. 500 nm is used for the process. By using sinter material with nano-scale silver, the processing temperature can be lowered considerably so that temperatures of less than 300° C., preferably less than 280° C., further preferred from 200° C. to 250° C. can be yielded.

These temperatures are particularly far below the Curie-temperature of commonly used piezo elements, so that their piezoelectric features and their polarization is preserved and thus a renewed polarization of the piezo elements can be avoided.

Alternatively, there are sintering films, which render the application of a paste unnecessary.

With the lower temperature, the present method allows to reduce mechanic stress between the individual components of the piezoelectric transmission and/or reception device.

Further, when using a sinter paste with nano-scaled silver, here the sintering can occur at a pressure of less than 20 MPa, preferably at 10 MPa, further preferred at atmospheric pressures. This way, the equipment required for the sintering process can be a lot less expensive and costs can be saved.

In particular, the sintering process can occur at ambient pressure and preferably at ambient air.

### DETAILED DESCRIPTION OF THE FIGURES

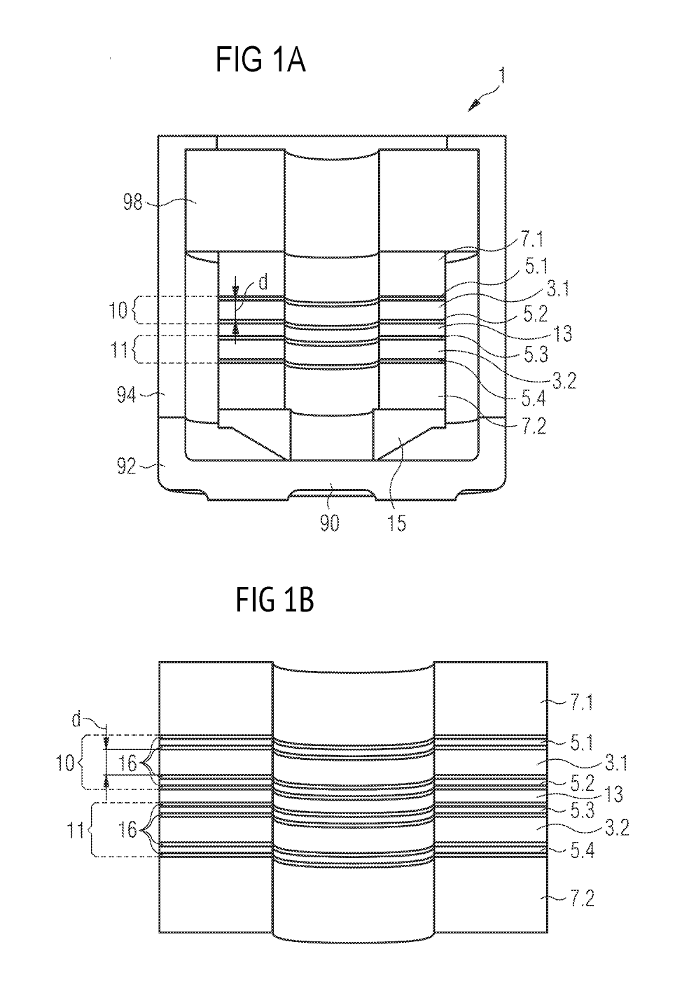

FIG. 1a shows a cross-section of a first exemplary embodiment of a piezoelectric transmission and/or reception device 1 according to the present invention.

The piezoelectric transmission and/or reception device 1 according to FIG. 1a is designed in a laminar fashion and shows, isolated from each other via a separating ceramic 13, a transmission device 10 and a reception device 11, with the sequence potentially being inverted as well.

The transmission device 10 and the reception device 11 are each embodied with a piezo element 3.1, 3.2, each electrically contacted via electrodes 5.1, 5.2; 5.3, 5.4. In the embodiment shown in FIG. 1, the transmission device 10 is arranged above the reception device 11; with a separating ceramic being located between the transmission device 10 and the reception device 11. An isolation element 7.1, 7.2 is arranged above the transmission device 10 as well as below the reception device 11, respectively embodied as a ceramic disk. In a diaphragm-side end of the stack, a further pressure part 15 is arranged, which is located below the isolation element 7.2.

All above-described components are sintered via a sintering process based on a sinter paste with nano-scaled silver to form a mono-block. This allows, in particular, that the piezo elements 3.1, 3.2 can be formed with a thickness d of less than 1.0 mm, since due to the embodiment of the piezoelectric transmission and/or reception device 1 as a mono-block as well as the sinter paste used for the sintering process mechanic influences upon the piezo elements 3.1, 3.2 can be largely avoided and uneven surface characteristics, which may lead to negative mechanic influences upon the piezo elements 3.1, 3.2, are compensated by the sinter paste.

Alternatively, a sinter film may also be used with respective characteristics.

The piezoelectric transmission and/or reception device 1 in the exemplary embodiment shown in FIG. 1a is inserted into a housing 94 embodied sheath-like in the circumferential direction and limited at the bottom by a diaphragm 90. The housing 94 and the diaphragm 90 are connected to each other at a diaphragm brim 92 extending perpendicular to the diaphragm, for example welded. Using a clamping disk 98 the piezoelectric transmission and/or reception device 1 are clamped to the diaphragm 90. The clamping disk 98 can either be fixed itself in the housing 94 or via a clamping device 96, not shown in greater detail in FIG. 1.

FIG. 1b shows a detail of FIG. 1a in an elevated illustration. FIG. 1b clearly discloses that between the piezo elements 3.1, 3.2 and the electrodes 5.1, 5.2, 5.3, 5.4 as well as between electrodes 5.2, 5.3 facing the separating ceramic 13 and the separating ceramic 13 and the electrodes 5.1, 5.4 arranged at the ends and the isolation elements 7.1, 7.2 respectively a sinter layer 16 is shown in FIG. 1b with an excessive thickness to increase clarity.

The sinter layer 16 is here formed by the residue of the sinter paste and generates a mechanical as well as conductive connection between the electrodes 5.1, 5.2; 5.3, 5.4 and the piezo elements 3.1, 3.2 and/or a mechanic connection to the separating ceramic 13 and the isolation elements 7.1, 7.2

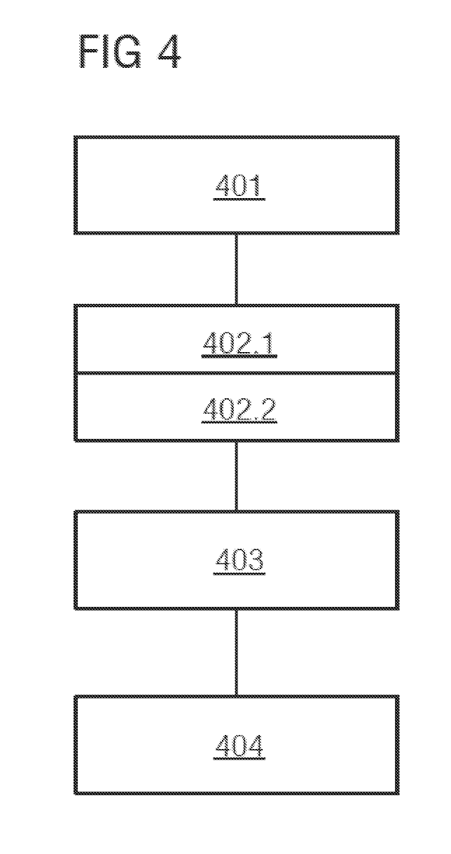

For the production of the piezoelectric transmission and/or reception device, the individual components of the piezoelectric transmission and/or reception device 1, as initially shown in FIG. 4 (401) and subsequently coated at its respectively facing sides with the sinter paste (402.1). The coating process can occur for example with a template printing process, a dispenser, or serigraphy.

Alternatively, silver-sinter films may also be used.

Subsequently, the components are subjected to a drying step (402.2), then arranged in reference to each other in a centered fashion in a stack (403), and sintered at a temperature of 250° C. and a pressure of 10 to 20 MPa for 1 to 3 minutes to form a mono-block (404).

When using a sinter film here a drying step is mandatory.

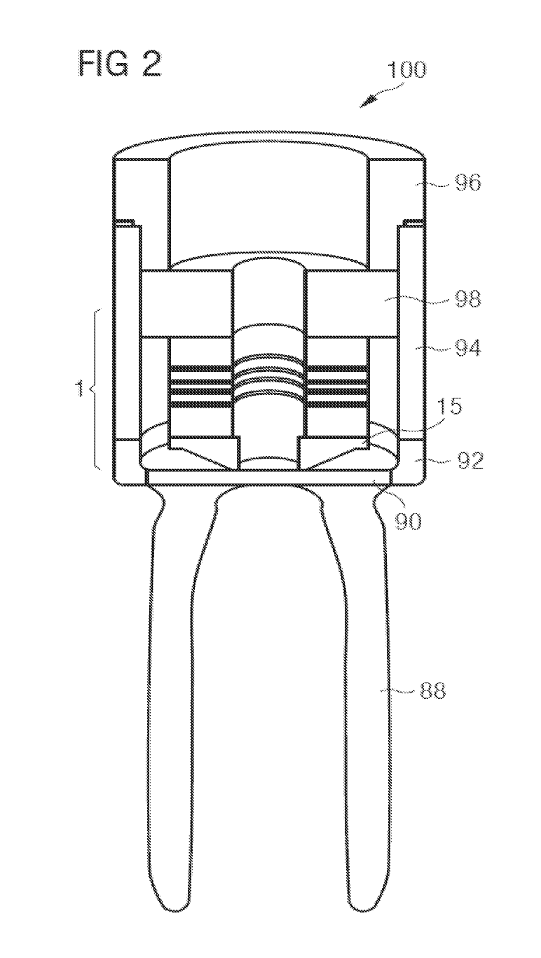

In a cross-section, FIG. 2 shows a vibration sensor 100 embodied as a vibration limit switch with a piezoelectric transmission and/or reception device 1 according to FIG. 1.

As discernible from FIG. 2, the piezoelectric transmission and/or reception device 1 is inserted into the housing 94 of the vibration sensor 100 and clamped via the clamping disk 98, and a clamping device 96 threaded into the housing 94 in the direction of the diaphragm 90. Due to the fact that the entire piezoelectric transmission and/or reception device 1 is sintered to form a mono-block, in the exemplary embodiment shown in FIG. 2, additional elements for centering the piezoelectric transmission and/or reception device 1 are waived.

At the front, a mechanic vibrator 88 is arranged at the diaphragm 90, which vibrates like a tuning fork depending on the thickness and viscosity of a medium surrounding it at a resonance frequency such that a covering of the mechanic oscillator 88 with a medium can be detected by way of measuring the resonance frequency.

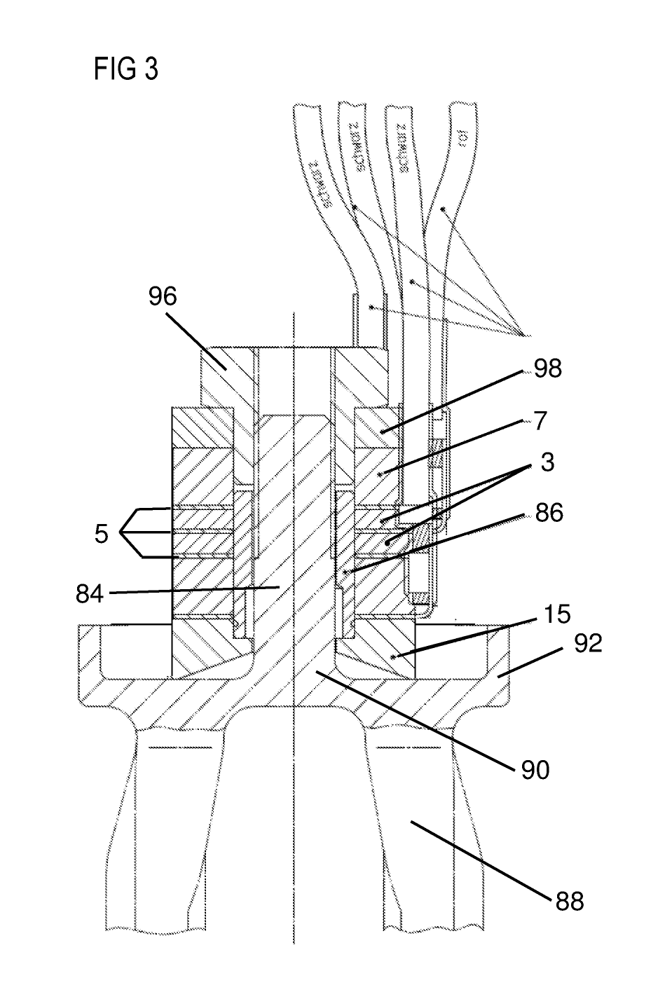

FIG. 3 shows a vibration sensor 100 with a second exemplary embodiment of a piezoelectric transmission and/or reception device 1, with the piezoelectric transmission and/or reception device 1 in the present embodiment comprising two piezo elements 3 with three electrodes 5 contacting the piezo element 3. As discernible in FIG. 3, an electrode 5 is provided respectively at the top and the bottom between the piezo elements 3, with the stack with insolation elements 7 at the top and the bottom continuing and being isolated. At the side of the diaphragm, a pressure part 15 is arranged in the stack. The above-described components are, as explained above, sintered to form a mono-block such that they can be handled as a unit.

The exemplary embodiment shown in FIG. 3 illustrates the design of a vibration sensor as known from prior art, with the drive according to prior art being replaced by a drive according to the present invention, namely a transmission and/or reception device 1 sintered to form a mono-block.

The clamping device 96 is formed in the exemplary embodiment shown in FIG. 3 as a clamping screw, which cooperates with a centrally arranged tension bolt 84. A force generated by the screw-connection of the clamping device 96 with the tension bolt 84 is transferred via the clamping disk 98 to the mono-block, which is clamped this way against the diaphragm 90. At the diaphragm 90, in turn a mechanic oscillator 88 is provided, which interacts in the manner described above with a medium surrounding it.

### LIST OF REFERENCE NUMERALS

1 piezoelectric transmission and/or reception device
3 piezo element
3.1 piezo element
3.2 piezo element
5 electrode
5.1 electrode
5.2 electrode
5.3 electrode
5.4 electrode
7.1 isolation element
7.2 isolation element
10 isolation elements
11 reception element
13 separating ceramic
15 pressure part
16 sinter layer
84 tension bolt
86 isolation sheath
88 mechanic oscillator
90 diaphragm
92 edge
94 housing
96 clamping device
98 clamping disk
100 vibration sensor
d thickness
t sinter period
T sinter temperature
p pressure

We claim:

1. A piezoelectric transmission and/or reception device comprising
at least one piezo element,
at least two electrodes for contacting the piezo elements, as well as
at least two isolation elements for isolation at the top and the bottom,
wherein at least the piezo element and the electrodes are sintered to form a mono-block.

2. The piezoelectric transmission and/or reception device according to claim 1, wherein the mono-block also comprises the isolation elements.

3. The piezoelectric transmission and/or reception device according to claim 1, wherein the piezoelectric transmission and/or reception device comprises n-piezo elements and n+1 electrodes, which piezo elements and electrodes are arranged in an alternating fashion and are sintered to form a mono-block.

4. The piezoelectric transmission and/or reception device according to claim 1, wherein the piezoelectric transmission and/or reception device comprises a transmission device and a reception device, which respectively comprise n-piezo elements, which are arranged in an alternating fashion, with the transmission device and the reception device being electrically isolated from each other by the separating ceramic and all components being sintered to form a mono-block.

5. A piezoelectric transmission and/or reception device according to claim 1, wherein the mono-block comprises additionally a preferably metallic pressure part for transmitting any oscillation generated.

6. The piezoelectric transmission and/or reception device according to claim 1, wherein the piezo elements and the electrodes are embodied as annular disks.

7. The piezoelectric transmission and/or reception device according to claim 1, wherein the piezo elements and the electrodes are embodied as annular disks.

8. The piezoelectric transmission and/or reception device according to claim 1, wherein the piezo elements show a thickness of less than 1.0 mm.

9. The piezoelectric transmission and/or reception device according to claim 1, wherein the piezo elements and/or the electrodes and/or the isolation elements and/or the separating ceramic show an average surface roughness of more than RZ 6.3.

10. A piezoelectric transmission and/or reception device according to claim 1, wherein the mono-block is produced via a silver-sintering process.

11. A vibration sensor with a piezoelectric transmission and/or reception device with a diaphragm that can be made to vibrate, a clamping device for clamping the piezoelectric transmission and/or reception device towards the diaphragm such that oscillations of the transmission and/or reception device are transferred to the diaphragm and the oscillations of the diaphragm to the transmission and/or reception device, wherein the transmission and/or reception device are embodied according to claim 1.

12. A method for the production of a piezoelectric transmission and/or reception device with the following steps:
providing at least one piezo element, at least two electrodes for contacting the piezo element, as well as at least two isolation elements for isolation at the top and the bottom,
coating at least the piezo element on its contacting sides as well as the electrodes on their sides facing the piezo element in the finished state of the arrangement with a sinter material on a silver base,
aligned arrangement of electrodes and piezo element in a stack, and
sintering the stack for a predetermined sintering period at a defined sinter temperature to form a mono-block.

13. The method according to claim 12, wherein the coating process comprises the application of a sinter paste via template printing, a dispenser, or serigraphy, or the application of a sinter film.

14. The method according to claim 12, wherein the coating process comprises a drying step after the application.

15. The method according to claim 12, further comprising wherein a sintering material is used comprising silver particles with a size from 100 nm to 500 nm.

16. The method according to any of claim 12, wherein the sinter temperature amounts to less than 300° C.

17. The method according to any of claim 12, wherein the sintering process occurs at a pressure of less than 20 MPa.
